(19) United States
(12) Patent Application Publication
(10) Pub. No.: US 2025/0201949 A1
(43) Pub. Date: Jun. 19, 2025

(54) SECONDARY BATTERY CHARGE/DISCHARGE DEVICE

(71) Applicant: EV Motors Japan Co., Ltd., Kitakyushu-shi, Fukuoka (JP)

(72) Inventor: Yuji Sato, Kitakyushu-shi, Fukuoka (JP)

(73) Assignee: EV Motors Japan Co., Ltd., Kitakyushu-shi, Fukuoka (JP)

(21) Appl. No.: 18/845,245

(22) PCT Filed: Mar. 10, 2022
(86) PCT No.: PCT/JP2022/010681

§ 371 Date: Sep. 9, 2024

(51) Int. Cl. H01M 10/44; G01R 31/36; G01R 31/364; H01M 10/42

(52) U.S. Cl. CPC H01M 10/441; G01R 31/364; G01R 31/3644; H01M 10/4285

(57) ABSTRACT

This invention is concerning a secondary battery charge/discharge device 10 for performing charge and discharge tests on a plurality of secondary batteries 11. The secondary battery charge/discharge device 10 comprises a power supply unit 12 and a contact unit 14 detachably mounted on a container 13 housing the plurality of secondary batteries 11, and the power supply unit 12 and the plurality of secondary batteries 11 housed in the container 13 are connected in series through the contact unit 14 when used.

### TECHNICAL FIELD

The present invention relates to a secondary battery charge/discharge device for collectively performing charge and discharge tests on a plurality of secondary batteries.

### BACKGROUND ART

Nowadays, the demand for secondary batteries (lithium-ion batteries) used in IT devices such as smartphones and electric vehicles is rapidly increasing. In the final process of the secondary battery mass production factory, a charge/discharge test device that activates the produced secondary batteries and inspects their quality is widely used. The device makes it possible to mechanize (automate) the activation and quality inspection of secondary batteries, which has been performed manually until then, and contributes to the realization of mass production of secondary batteries.

However, in many conventional charge/discharge test devices, a contact unit (also called a fixture unit) for electrically connecting a power supply unit and secondary batteries is provided in a case independent of the power supply unit, and a cable has been used to connect both units. Consequently, there are adverse effects such as heat generation from this cable, the influence of noise due to cable routing, and power loss caused by increased resistance due to lengthening of the cable.

Therefore, in order to eliminate these adverse effects, for example, Patent Document 1 discloses a device in which a power supply unit and a contact unit are integrated to eliminate the need for a cable or to shorten the cable as much as possible and which has a cooling mechanism. As a result, stable operation of the device is realized while making the entire device compact.

### CITATION LIST

### Patent Literature

Patent Document 1: Japanese Unexamined Patent Application Publication No. 2019-46615

### SUMMARY OF INVENTION

### Technical Problem

Patent Document 1 employs a parallel connection method that has been mainly used in a constant current constant voltage (CC-CV) type charge/discharge test device for a secondary battery, and it is excellent in ensuring the safety of the secondary battery during charge and discharge test. On the other hand, there is a problem that the device tends to be complicated, large in size, and costly, since a high-performance, expensive, and large-sized charge/discharge power supply (power supply unit) that can output and control high voltage and high current is required for constant current charge/discharge. In particular, when the secondary battery has a large current capacity, since the power supply unit becomes larger in size correspondingly to the capacity of the secondary battery, there arises a problem that the weight of the entire device is increased and the structure is complicated, which leads to a decrease in handling properties. Furthermore, there is also a problem that the test efficiency is deteriorated, since a high output charge/discharge power supply is used even at the time of constant voltage charging and discharging, which can normally be performed at low voltage and low current.

Moreover, since the power supply unit is integrated with the contact unit and probes, when the power supply unit fails, it is difficult to remove and repair only the power supply unit or replace the failed power supply unit with a new power supply unit. Therefore, there is a problem that maintainability is lowered. In particular, in recent years, with the widespread use of electric vehicles, there are various forms of secondary batteries with different shapes and sizes in the second-hand market, and in order to test them, it is necessary to prepare a plurality of different devices for each form (type) of secondary battery to be tested. Therefore, it is difficult to expand the second-hand market, and there is also a problem that secondary batteries that have not reached the end of their service life and reusable secondary batteries are discarded without being effectively used. Additionally, since the probes are fixed on the substrate, it is difficult to make the probes follow the positions of the electrodes that move with the expansion and contraction of each of the secondary batteries during the charge and discharge tests, and there is also a problem of lack of reliability and stability of electrical connection.

The present invention has been made in consideration of the above circumstances, and has as its object to provide a secondary battery charge/discharge device, which simplifies the wiring of the contact unit that electrically connects the power supply unit and a plurality of secondary batteries, can support testing of various forms of secondary batteries simply by replacing the contact unit according to the form of the secondary battery, has excellent maintainability and versatility, can make the entire device compact and reduce running costs, and has excellent energy saving and test efficiency.

### Solution to Problem

In order to achieve the above object, according to an aspect of the present invention, there is provided a secondary battery charge/discharge device for performing charge and discharge tests on a plurality of secondary batteries, the secondary battery charge/discharge device comprising:
a power supply unit; and
a contact unit detachably mounted on a container housing the plurality of secondary batteries,
wherein the power supply unit and the plurality of secondary batteries housed in the container are connected in series through the contact unit when used.

In the secondary battery charge/discharge device according to the aspect of the present invention, it is preferable that the contact unit be replaceable depending on a type of the secondary batteries.

In the secondary battery charge/discharge device according to the aspect of the present invention, it is preferable that the power supply unit has a paired positive and negative terminal, and the contact unit has a plurality of contact probes, a positive side connection terminal and a negative side connection terminal, and when in use, each of the contact probes is electrically connected to a respective positive or negative electrode of each of the secondary batteries housed in the container, the positive side connection terminal is electrically connected to the positive terminal and the negative side connection terminal is electrically connected to the negative terminal.

In the secondary battery charge/discharge device according to the aspect of the present invention, it is preferable that the contact unit has a following mechanism for moving each of the contact probes following movement of the respective positive and negative electrode accompanying expansion and contraction of each of the secondary batteries during charging and discharging.

### Advantageous Effects of Invention

In the secondary battery charge/discharge device according to the present invention, since the power supply unit can be downsized to reduce power consumption, it is excellent in energy saving, and at the same time, it is possible to support testing of various types of secondary batteries by replacing the contact unit, so that it is excellent in maintainability and versatility.

### BRIEF DESCRIPTION OF DRAWINGS

FIG. 1 is a side view illustrating a usage state of a secondary battery charge/discharge device according to an embodiment of the present invention.

FIG. 2 is a plan view illustrating a state in which a plurality of secondary batteries are housed in a container of the secondary battery charge/discharge device.

FIG. 3 is a side view illustrating a state in which a plurality of the secondary batteries are housed in the container of the secondary battery charge/discharge device.

FIG. 4 is a front view of the container of the secondary battery charge/discharge device.

FIG. 5 is a plan view illustrating a contact unit of the secondary battery charge/discharge device.

FIG. 6 is a cross-sectional view taken along the line A-A of FIG. 5.

FIG. 7 is a cross-sectional view taken along the line B-B of FIG. 5.

### DESCRIPTION OF EMBODIMENTS

Subsequently, with reference to the accompanying drawings, descriptions will be given on embodiments of the present invention for a better understanding of the present invention.

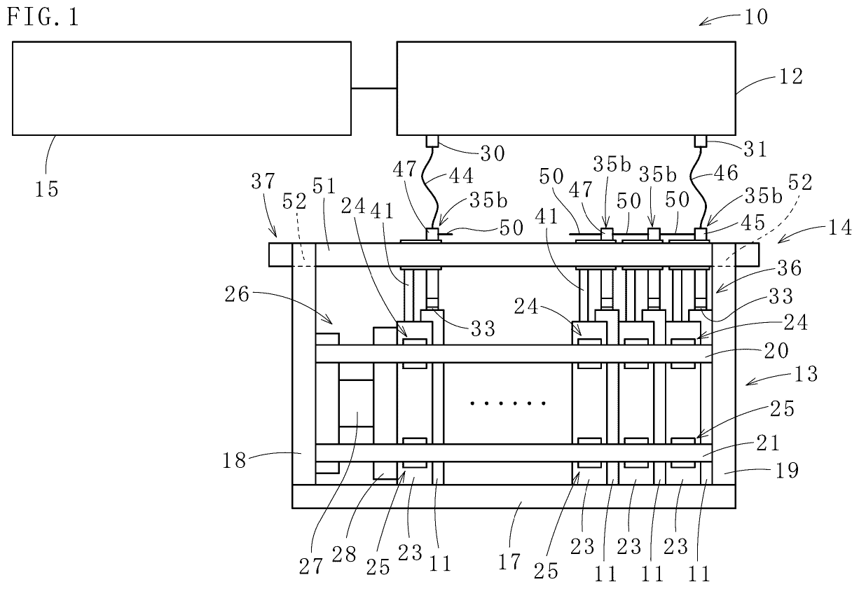

A secondary battery charge/discharge device 10 according to an embodiment of the present invention illustrated in FIG. 1 is used for testing on secondary batteries 11 such as lithium-ion batteries, and is for charging and discharging a plurality of the secondary batteries 11 at one time. Note that the left-right direction and the depth direction (direction perpendicular to the paper surface) in FIG. 1 will be described as the front-rear direction and the width direction of the secondary battery charge/discharge device 10, respectively.

The secondary battery charge/discharge device 10 has a power supply unit 12 and a contact unit 14 that is detachably mounted on a container 13 in which the plurality of secondary batteries 11 are housed, and the power supply unit 12 and the secondary batteries 11 housed in the container 13 are connected in series through the contact unit 14 when used.

Here, although the power supply unit 12 is composed of an AC-DC converter, a DC-DC converter, and the like, it is desirable that the power supply unit 12 can be charged and discharged with CC-CV (constant current constant voltage) when the secondary battery 11 is a lithium-ion battery.

Furthermore, the secondary battery charge/discharge device 10 is controlled by a charge/discharge controller 15. As the charge/discharge controller 15, a computer having a storage means such as a hard disk, a display means such as a display, and an input means such as a keyboard, a mouse, a touch panel, or a touch pad is preferably used, and various controls such as instructions for starting and ending the test, and setting of test conditions can be performed through dedicated software stored in the storage means. The charge/discharge controller and the power supply unit may be connected using an electric wire for transmitting and receiving electric signals, or may be wirelessly connected by using Wi-Fi communication or the like.

In this embodiment, the secondary battery charge/discharge device 10 is composed of one power supply unit 12, one container 13, one contact unit 14, and one charge/discharge controller 15, but multiple sets, each set consisting of one power supply unit 12, one container 13 and one contact unit 14, can be controlled by one charge/discharge controller 15.

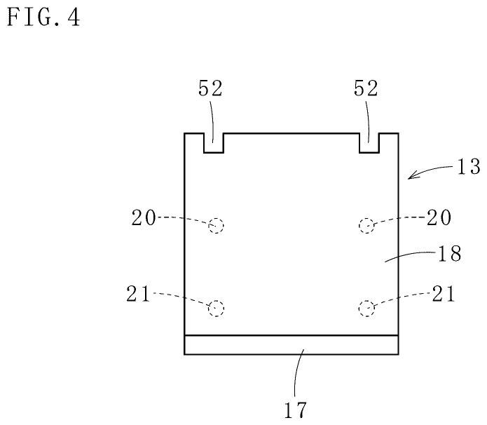

As illustrated in FIGS. 1 to 4, the container 13 has a base portion 17, and a front plate 18 and a rear plate 19 erected on both sides of the base portion 17 in a longitudinal direction (that is, the front-rear direction of the secondary battery charge/discharge device 10 and the left-right direction of FIGS. 1 to 3), respectively. Additionally, each side of the front plate 18 in the width direction and each side of the rear plate 19 in the width direction are connected by two columnar side connecting members 20 and 21 at upper and lower positions. Furthermore, as illustrated in FIGS. 1 to 3, a plurality of secondary batteries 11 and a plurality of spacers 23 are housed in the container 13 along the longitudinal direction while being alternately arranged in the thickness direction of each secondary battery 11 and each spacer 23 on the base portion 17.

Engagement portions 24, 25 are formed at two upper and lower positions, respectively, on each of both outer sides in the width direction of each of the spacers 23. The engagement portions 24, 25 engage with the side connecting members 20, 21, respectively, so as to sandwich the side connecting members 20, 21 from above and below. As a result, the spacers 23 are guided by the side connecting members 20 and 21, and can smoothly slide on the base portion 17 together with the secondary batteries 11 along the longitudinal direction of the container 13.

The cross-sectional shape, number, and arrangement of side connecting members are not limited to the present embodiment, and are appropriately selected. Accordingly, the shape, number, and arrangement of engagement portions of the spacer are also appropriately.

Moreover, in the present embodiment, the spacer 23 is formed in a substantially U-shape in a plan view, but the shape of the spacer is not limited to the shape of this embodiment, and is appropriately selected. For example, it may be formed in a substantially I-shape in a plan view or simply in a flat plate shape.

Furthermore, a pressing means 26 is attached to the inner side of the front plate 18 of the container 13. A hydraulic cylinder or the like is preferably used as the pressing means 26, and a flat plate-shaped pressing portion 28 is attached to the tip side of a rod 27 of the pressing means 26. With such a configuration, by driving the pressing means 26, the pressing portion 28 is pressed against the spacer 23 closest to the front plate 18, and a plurality of secondary batteries 11 and a plurality of spacers 23 alternately arranged side by side can be pressed toward the rear plate 19 with a constant force. As a result, the secondary batteries 11 and the spacers 23 can be arranged at substantially equal intervals in the initial state. Even if each secondary battery 11 repeatedly expands and contracts during charging and discharging, the intervals between the secondary batteries 11 and the intervals between the spacers 23 are repeatedly expanded and contracted substantially evenly by keeping the pressing force of the pressing means 26 constant, and are kept approximately equal regardless of the location.

The pressing means only needs to be able to press the secondary batteries and the spacers, which are housed in the container, with a constant force, and the structure, arrangement and the like are appropriately selected. For example, two pressing means may be arranged on the inner side of the front plate and on the inner side of the rear plate, respectively, so as to face each other, and the secondary batteries and the spacers may be pressed by the pressing means from the front and rear of the container. Alternatively, a pressing means may be installed on the charge/discharge stage on which the container is placed, and the secondary batteries and the spacers may be pressed by the pressing means penetrating the front plate (or the rear plate) from the outside of the container.

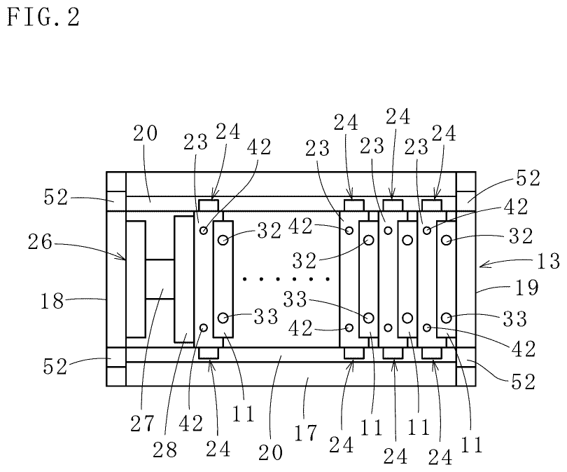

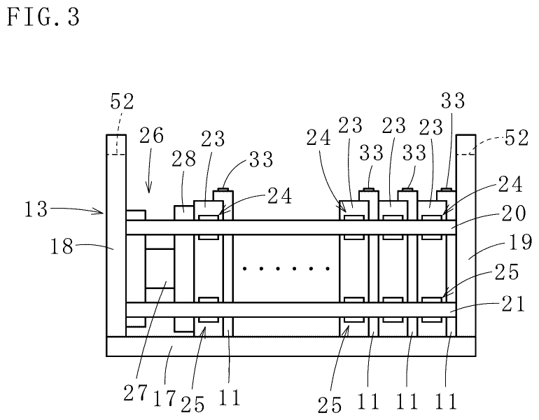

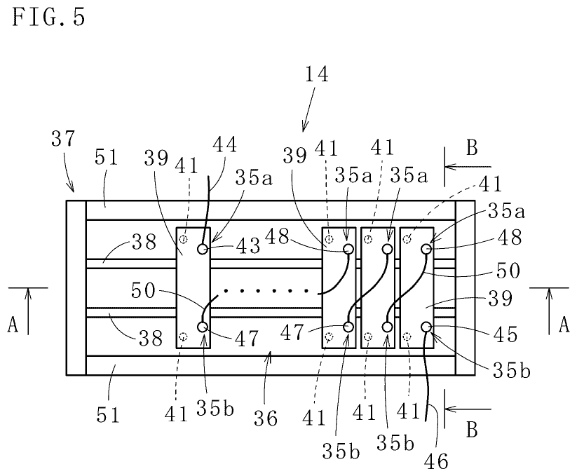

As illustrated in FIG. 1, the power supply unit 12 has a pair of positive and negative terminals 30 and 31. Further, as illustrated in FIG. 2, a positive electrode 32 and a negative electrode 33 are arranged side by side on the upper surface of each of the secondary batteries 11 housed in the container 13, but in FIGS. 1 and 3, only the negative electrodes 33 on the front side are visible. Moreover, as illustrated in FIG. 5, the contact unit 14 has a plurality of pairs of contact probes 35a and 35b, and each pair of contact probes 35a and 35b respectively corresponds to the positive electrode 32 and the negative electrode 33 (see FIG. 2) of each of the secondary batteries 11 housed in the container 13. As a result, each pair of contact probes 35a and 35b are respectively electrically connected to the positive and negative electrodes 32 and 33 of each of the secondary batteries 11 housed in the container 13 when used. In FIG. 1, only the contact probes 35b on the front side are visible. Note that a positive electrode current output line and a positive electrode voltage detection line are incorporated in the contact probe 35a corresponding to the positive electrode 32, and a negative electrode current output line and a negative electrode voltage detection line are incorporated in the contact probe 35b corresponding to the negative electrode 33, thereby enabling charge/discharge and voltage measurement of each secondary battery 11.

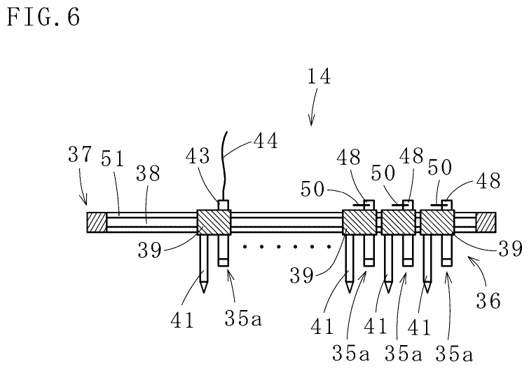

Furthermore, as illustrated in FIGS. 5 to 7, the contact unit 14 has a following mechanism 36 that moves each pair of contact probes 35a and 35b following the movement of the positive and negative electrodes 32 and 33 of each secondary battery 11 accompanying expansion and contraction of each secondary battery 11 during charging and discharging. This following mechanism 36 has two round bar-shaped guide members 38 arranged on the left and right along the front-rear direction of the contact unit 14 (that is, the thickness direction of each secondary battery 11 and also the left-right direction of FIGS. 1 to 3, 5 and 6), and a plurality of probe holding members 39 each holding the paired contact probes 35a and 35b corresponding to the positive and negative electrodes 32 and 33 of each of the secondary batteries 11, respectively, inside a frame body 37 of the contact unit 14 formed in a rectangular shape in plan view. As a result, by inserting the guide members 38 respectively into fitting holes 40 formed at two locations in the width (left and right) direction of each probe holding member 39 and penetrating each probe holding member 39 in the front-rear direction, each probe holding member 39 is held so as to be slidable in the front-rear direction of the contact unit 14 along the guide members 38. Furthermore, positioning pins 41 protruding downward are attached to the lower surface of each probe holding member 39 at two locations in the width (left and right) direction. Additionally, as illustrated in FIG. 2, positioning holes 42 corresponding to the two positioning pins 41 (see FIG. 5) of each probe holding member 39 are formed at two locations in the width (left and right) direction of the upper surface of each spacer 23.

Therefore, when the secondary battery charge/discharge device 10 is used, as illustrated in FIG. 1, the contact unit 14 is placed above the container 13 in which the secondary batteries 11 are housed, and the positioning pins 41 of each probe holding member 39 are inserted into the positioning holes 42 of each spacer 23, respectively. As a result, the contact probes 35a and 35b held by each probe holding member 39 are positioned on the positive and negative electrodes 32 and 33 of each secondary battery 11, respectively, and they are electrically connected.

Moreover, the upper end of the contact probe 35a held by the probe holding member 39 in the very front is electrically connected to the positive terminal 30 by a cable 44 as a positive side connection terminal 43, and the upper end of the contact probe 35b held by the probe holding member 39 in the very back is electrically connected to the negative terminal 31 by a cable 46 as a negative side connection terminal 45. At this time, as illustrated in FIG. 5, of the probe holding members 39 adjacent to each other in the front-rear direction of the contact unit 14, the upper end portion 47 of the contact probe 35b of the probe holding member 39 on the front side and the upper end portion 48 of the contact probe 35a of the probe holding member 39 on the rear side are sequentially connected by a cable (or flexible conductor) 50 in advance.

Therefore, at the time of use, as described above, the power supply unit 12 and the plurality of secondary batteries 11 can be connected in series simply by bringing the tips of the contact probes 35a and 35b held by each of the probe holding members 39 into contact with the positive electrode 32 and the negative electrode 33 of each of the secondary batteries 11, respectively, for electrical connection, and then electrically connecting the positive side connection terminal 43 and the negative side connection terminal 45 of the contact unit 14 to the positive terminal 30 and the negative terminal 31 of the power supply unit 12 with the cables 44 and 46, respectively.

As described above, as each of the secondary batteries 11 expands and contracts during charging and discharging, the positive electrode 32 and the negative electrode 33 of each of the secondary batteries 11 move in the front-rear direction of the container 13. However, since each spacer 23 and each probe holding member 39 are integrated by inserting the positioning pins 41 of each probe holding member 39 into the positioning holes 42 of each spacer 23, each pair of contact probes 35a and 35b moves together with each spacer 23 following movement of the positive electrode 32 and the negative electrode 33 of each secondary battery 11 to maintain a stable electrical connection state. At this time, each of the cables 44, 46, and 50 has a length that takes into consideration the movement of each probe holding member 39 (each pair of contact probes 35a and 35b) and is loose in the initial state. Therefore, even if each probe holding member 39 moves, no load is applied to each of the cables 44, 46, and 50 and each of the contact probes 35a, 35b, etc., and disconnection can be prevented.

Note that the following mechanism only needs to be able to move each contact probe by following the movement of each positive electrode and each negative electrode due to expansion and contraction of each secondary battery during charging and discharging, and its structure is not limited to this embodiment. For example, the number and arrangement of guide members and fitting holes can be selected as appropriate, and fitting grooves may be used instead of fitting holes.

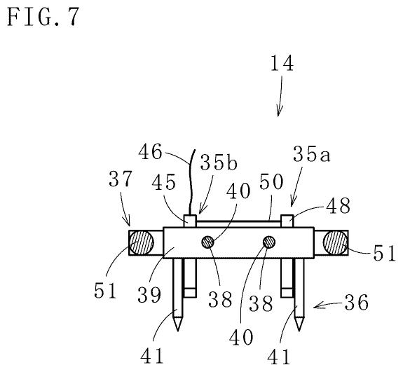

Additionally, in this embodiment, as illustrated in FIG. 7, each of longitudinal frame members 51 that constitute the frame body 37 of the contact unit 14 has a circular cross section, and as illustrated in FIGS. 1 to 4, rectangular notches 52 are formed on both sides in the width (left-right) direction of the upper surface of each of the front and rear plates 18 and 19 of the container 13. As a result, when the contact unit 14 is mounted on the container 13, the contact unit 14 can be held (fixed) at a predetermined position on the container 13 by engaging each longitudinal frame member 51 with the corresponding notches 52. However, the structure (holding method) for mounting the contact unit on the container is not limited to this, and is appropriately selected.

The secondary battery charge/discharge device 10 has a structure in which the contact unit 14 for electrically connecting the power supply unit 12 and a plurality of the secondary batteries 11 housed in the container 13 is independent of the power supply unit 12 and the container 13, and is detachably mounted on the container 13. Therefore, by preparing a plurality of types of containers and a plurality of types of contact units, and appropriately combining them, the secondary battery charge/discharge device 10 can correspond to various forms (types) of secondary batteries. In particular, in the second-hand market where various types of secondary batteries are on the market, there is no need to prepare a secondary battery charge/discharge device for each type of secondary battery, thereby reducing costs and expanding distribution.

Although the embodiment of the present invention has been described above, the present invention is not limited to the configuration described in the above-described embodiment, and includes other embodiments and modifications conceivable within the scope of the matters described in the scope of the claims.

### INDUSTRIAL APPLICABILITY

The secondary battery charge/discharge device according to the present invention simplifies the wiring of the contact unit that electrically connects the power supply unit and a plurality of secondary batteries, can support tests of various forms of secondary batteries simply by replacing the contact unit according to the form of the secondary batteries, and is excellent in maintainability and versatility. Furthermore, by connecting the power supply unit and a plurality of secondary batteries in series, the entire device can be made compact and running costs can be reduced, which can contribute to the spread of secondary batteries.

### REFERENCE SIGNS LIST

10: secondary battery charge/discharge device, 11: secondary battery, 12: power supply unit, 13: container, 14: contact unit, 15: charge/discharge controller, 17: base portion, 18: front plate, 19: rear plate, 20, 21: side connecting members, 23: spacer, 24, 25: engagement portions, 26: pressing means, 27: rod, 28: pressing portion, 30: positive terminal, 31: negative terminal, 32: positive electrode, 33: negative electrode, 35a, 35b: contact probes, 36: following mechanism, 37: frame body, 38: guide member, 39: probe holding member, 40: fitting hole, 41: positioning pin, 42: positioning hole, 43: positive side connection terminal, 44: cable, 45 negative side connection terminal, 46: cable, 47, 48: upper end portions, 50: cable, 51: longitudinal frame member, 52: notch

1. A secondary battery charge/discharge device for performing charge and discharge tests on a plurality of secondary batteries, the secondary battery charge/discharge device comprising:
a power supply unit; and
a contact unit detachably mounted on a container housing the plurality of secondary batteries,
wherein the power supply unit and the plurality of secondary batteries housed in the container are connected in series through the contact unit when used.

2. The secondary battery charge/discharge device according to claim 1, wherein the contact unit is replaceable depending on a type of the secondary batteries.

3. The secondary battery charge/discharge device according to claim 1, wherein the power supply unit has a paired positive and negative terminal, and the contact unit has a plurality of contact probes, a positive side connection terminal and a negative side connection terminal, and when in use, each of the contact probes is electrically connected to a respective positive or negative electrode of each of the secondary batteries housed in the container, the positive side connection terminal is electrically connected to the positive terminal and the negative side connection terminal is electrically connected to the negative terminal.

4. The secondary battery charge/discharge device according to claim 3, wherein the contact unit has a following mechanism for moving each of the contact probes following movement of the respective positive and negative electrode accompanying expansion and contraction of each of the secondary batteries during charging and discharging.
